(19) United States
(12) Patent Application Publication
(10) Pub. No.: US 2008/0193861 A1
(43) Pub. Date: Aug. 14, 2008

(54) METHOD FOR REPAIRING A DEFECT ON A PHOTOMASK

(75) Inventor: Ku Cheol JEONG, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/966,442

(22) Filed: Dec. 28, 2007

(30) Foreign Application Priority Data
Feb. 14, 2007 (KR) 10-2007-0015588

(51) Int. Cl. G03F 1/00

(52) U.S. Cl. 430/5

(57) ABSTRACT

A method for repairing a defect on a photomask includes coating a resist on a photomask substrate. The photomask substrate includes phase shift layer patterns formed on the photomask substrate, light blocking layer patterns formed over the phase shift layer patterns and a defect formed between adjacent phase shift layer patterns. The resist is etched to expose the defect such that the photomask substrate is not exposed. The defect is etched to remove the defect. The resist prevents the photomask substrate from being etched. The resist is then removed.

### CROSS-REFERENCES TO RELATED APPLICATIONS

The present application claims priority to Korean patent application number 10-2007-0015588, filed on Feb. 14, 2007, which is incorporated by reference in its entirety.

### BACKGROUND OF THE INVENTION

The present invention relates to a method for fabricating a semiconductor device and, more particularly, to a method for repairing a defect on a photomask without causing damage to a photomask substrate or a pattern.

A photolithography process refers to a semiconductor manufacturing process that includes the steps of uniformly coating a photoresist on a wafer, projecting a pattern formed on a mask or a reticle onto the wafer using exposure equipment, and developing the pattern to form a two-dimensional photoresist pattern. The pattern of the photomask is a source of a wafer pattern. Thus, the photomask has become important in the semiconductor manufacturing process as the integration degree of the semiconductor device increases. Such a photomask can be obtained by forming semiconductor microcircuits on a mask substrate. That is, a semiconductor IC (integrated circuit) is patterned on a transparent mask substrate by using a light blocking layer coated on an upper layer of the transparent mask substrate such that the size of the semiconductor IC is approximately one to five times as much as the original size to be formed on a wafer.

However, defects such as a pattern size defect or residues may occur in the photomask. Such defects occurring in the pattern of the photomask may cause a defect in a pattern of a photoresist when the pattern of the photomask is transferred onto the photoresist through an exposure process. Thus, the pattern formed on the photomask must be inspected after the photomask has been fabricated. If a defective pattern is formed on the photomask, the defective pattern must be repaired to obtain a desired pattern. A focused ion beam scheme is extensively used as a method of repairing the pattern of the photomask.

Conventionally, in order to repair undesired patterns or defects, an ion beam generator irradiates ion beams onto a defective part. In addition, appropriate gas is fed onto the defective part, thereby repairing the defective part. However, in the process of repairing the defective part using the ion beam, the mask substrate may be damaged. In this case, light passing through the defective part of the mask substrate may be scattered, or the amount of light passing through the defective part of the mask substrate may vary, so that the pattern is abnormally formed on the wafer. In addition, the ion beam may exert an influence upon a phase shift layer or a light blocking layer formed on the mask substrate. Further, if a misalignment occurs, a serious problem is caused. In this case, a problem may occur not only in the pattern size of the photomask, but also in the phase of transmission light, thereby causing a pattern defect.

### SUMMARY OF THE INVENTION

Embodiments of the present invention provide a method for repairing a defect on a photomask.

In one embodiment of the present invention, a method for repairing a defect on a photomask is disclosed. The method includes coating a resist on a photomask substrate. The photomask substrate includes phase shift layer patterns formed on the photomask substrate, light blocking layer patterns formed over the phase shift layer patterns and a defect formed on the photomask substrate between adjacent phase shift layer patterns. The resist is etched to expose the defect such that the photomask substrate is not exposed. The defect is etched to remove the defect. The resist prevents the photomask substrate from being etched. The resist is then removed.

The phase shift layer patterns include phase shift material. The phase shift layer patterns include a molybdenum silicon nitride (MoSiN) layer. The light blocking layer patterns include chrome (Cr). The defect includes material which is identical to material of the phase shift layer patterns. The resist includes a positive resist or a negative resist. The defect is removed through a dry etching process.

### BRIEF DESCRIPTION OF THE DRAWINGS

FIGS. 1 through 3B are sectional views illustrating a method for repairing a defect on a photomask according to embodiments of the present invention.

### DETAILED DESCRIPTION OF THE PREFERRED EMBODIMENTS

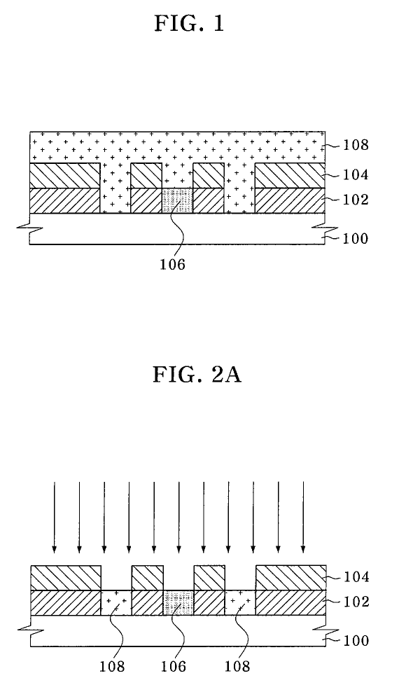

Referring to FIG. 1, a phase shift layer 102 and a light blocking layer 104 are formed on a mask substrate 100 through a typical process. The mask substrate 100 includes a transparent substrate, such as a quartz substrate. The phase shift layer 102 includes a phase shift material, such as molybdenum silicon nitride (MoSiN), in order to shift the phase of transmission light. In addition, the light blocking layer 104 includes a light blocking material, such as chrome (Cr).

As mentioned above, a defect 106 may occur on the mask substrate 100 in the process of patterning the phase shift layer 102 or the light blocking layer 104.

A resist 108 is coated on the entire surface of the mask substrate 100 including the light blocking layer 104. The resist 108 includes a positive photoresist or a negative photoresist.

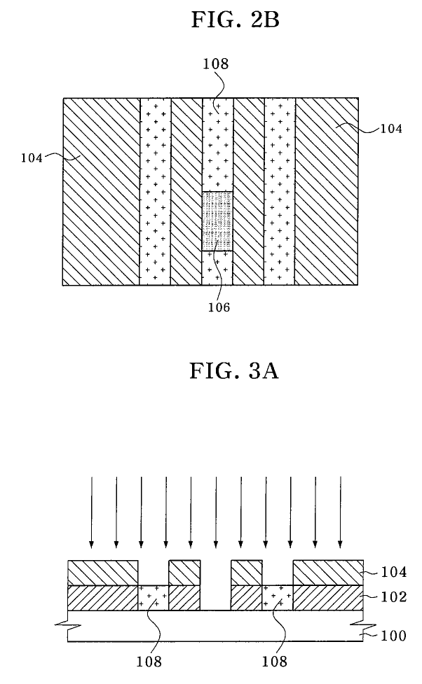

Referring to FIGS. 2A and 2B, an etch back process is performed on the entire surface of the resist 108 until the defect 106 is exposed. The etch back process is performed in a dry etching apparatus using an appropriate etching gas. FIG. 2A is a sectional view illustrating the etch back process being performed on the resist 108, and FIG. 2B is a plane view of FIG. 2A. As shown in FIGS. 2A and 2B, a surface of the defect 106 is exposed, and the resist 108 remains on a region of the mask substrate 100 where there is no defect. The resist 108 serves as an etch stop layer to protect the mask substrate 100 when the etching process is performed on the defect 106.

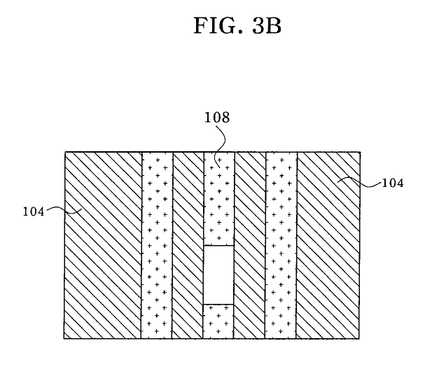

Referring to FIGS. 3A and 3B, a dry etching process is performed on the mask substrate 100 including the exposed defect by using etching gas, thereby removing the defect. Since the resist 108 is formed on the region of the mask substrate 100 where there is no defect, the defect can be removed through the etching process without causing damage to the mask substrate 100. As shown in FIG. 3B, the defect is removed from the mask substrate 100.

According to the method for repairing the defect occurring in the photomask of the present invention, the resist is coated on the entire surface of the mask substrate before the defect is removed from the mask substrate and then the etch back process is performed to form the resist pattern on the region of the mask substrate where there is no defect. The etching process is then performed to remove the defect. Therefore, the mask substrate can be prevented from being damaged by a mistake or misalignment in the process of repairing the defect.

Although preferred embodiments of the present invention have been disclosed for illustrative purposes, those skilled in the art will appreciate that various modifications, additions and substitutions are possible, without departing from the scope and spirit of the invention as defined in the accompanying claims.

What is claimed is:

1. A method for repairing a defect on a photomask, the method comprising:
coating a resist on a photomask substrate, wherein phase shift layer patterns are formed over the photomask substrate light blocking layer patterns are formed over the phase shift layer patterns, and a defect is formed on the photomask substrate between adjacent phase shift layer patterns;
etching the resist to expose the defect, wherein the photomask substrate is not exposed;
etching the defect such that the defect is removed, wherein the resist prevents the photomask substrate from being etched; and
removing the resist.

2. The method of claim 1, wherein the phase shift layer patterns include a phase shift material.

3. The method of claim 1, wherein the phase shift layer patterns include a molybdenum silicon nitride (MoSiN) layer.

4. The method of claim 1, wherein the light blocking layer patterns include chrome (Cr).

5. The method of claim 1, wherein the defect includes material which is identical to material of the phase shift layer patterns.

6. The method of claim 1, wherein the resist includes a positive resist or a negative resist.

7. The method of claim 1, wherein the defect is removed through a dry etching process.
